(19) United States
(12) Patent Application Publication
(10) Pub. No.: US 2006/0209619 A1
(43) Pub. Date: Sep. 21, 2006

(54) Data input circuit of synchronous semiconductor memory device using data sampling method for changing DQS domain to clock domain

(75) Inventor: Min-Sang Park, Yongin-si (KR)

Correspondence Address: F. CHAU & ASSOCIATES, LLC, 130 WOODBURY ROAD, WOODBURY, NY, 11797, US

(73) Assignee: Samsung Electronics Co. Ltd.

(21) Appl. No.: 11/365,653

(22) Filed: Mar. 1, 2006

(30) Foreign Application Priority Data
Mar. 17, 2005 (KR) 2005-22202

(51) Int. Cl. G11C 8/00

(52) U.S. Cl. 365/233

(57) ABSTRACT

Provided is a data input circuit of a semiconductor memory device. The data input circuit includes: an input buffer that samples an external data signal in response to a data strobe signal and outputs a first-sampled signal; a first domain converter that samples the first-sampled signal in response to a first clock signal and outputs a second-sampled signal; and a second domain converter that samples the second-sampled signal in response to a second clock signal containing write command information.

### CROSS-REFERENCE TO RELATED PATENT APPLICATIONS

This application claims priority to Korean Patent Application No. 10-2005-0022202, filed on Mar. 17, 2005, in the Korean Intellectual Property Office, the disclosure of which is herein incorporated by reference in its entirety.

### BACKGROUND OF THE INVENTION

1. Technical Field

The present invention relates to a semiconductor memory device and, more particularly, to a sampling method for enhancing a sampling margin between a data strobe signal and a clock signal to stably latch data in a synchronous semiconductor memory device.

2. Description of the Related Art

To increase the operating speeds of DRAMs, synchronous DRAMs (SDRAMs) which operate in synchronization with an external system clock signal have been developed. Double data rate (DDR) SRAMs and Rambus DRAMs that process data in synchronization with rising and falling edges of a clock signal feature increased data transfer rates.

In general, when a semiconductor memory device performs a write operation, external data is sampled with a data strobe signal (hereinafter, referred to as a ‘DQS’ signal) and the sampled signal is sampled again with an internal clock signal so as to synchronize the external data with the internal clock signal.

FIG. 1 is a block diagram of a conventional data input circuit 10 of a semiconductor memory device. Referring to FIG. 1, the conventional data input circuit 10 includes an input buffer 11, a delay unit 13, and a domain converter 15. The domain converter 15 may include a low-level sampler 17 and a high-level sampler 19.

The input buffer 11 latches data in response to a DQS signal. The domain converter 15 latches the latched data in response to a write clock signal (hereinafter, referred to as a ‘PCLK_WR’ signal) containing write command information. The delay unit 13 delays the data latched by the input buffer 11 by a predetermined time to compensate for a delay between the DQS signal and the PCLK_WR signal.

In conventional semiconductor memory devices, since data is transmitted at high speed, the data clock signal period is very short and a large amount of data is simultaneously received in parallel from different locations. However, since data input drivers that receive data are disposed in different areas, and since the lengths of signal lines to these data input drivers are different from each other, the power required for transmitting data is different for various data, causing data skews.

For example, in the conventional data input circuit 10 illustrated in FIG. 1, a data skew generated in a DQS domain is delayed by the delay unit 13 and then transmitted to a PCLK_WR domain. Moreover, the skew of the delay unit 13 is added to the data skew. These two combined skews generated in the DQS domain are added to the skew of the PCLK_WR domain when sampling is performed by a PCLK_WR signal.

For example, given a data clock signal period of 1 ns, if a skew of 500 ps is generated in the DQS domain and a skew of 300 ps is generated in the PCLK_WR domain, correct sampling is possible only within a timing margin of 200 ps when data is sampled in the domain converter 15. Such reduction in the timing margin makes it difficult to correctly perform sampling.

In addition, the PCLK_WR signal containing the write command information is controlled by a signal containing command decoding information. The DQS domain is disposed relatively near data input pads and the PCLK_WR domain is disposed relatively far from command input pads. Accordingly, a delay between a DQS signal and a PCLK_WR signal results. Generally, in high-frequency memory devices, the DQS path is relatively short.

For the above reasons, when a data input circuit of a memory device is designed, a delay unit 13 as illustrated in FIG. 1 may be added to compensate for a delay between a DQS signal and a PCLK_WR signal. However, in high-frequency memory devices, such delay compensation by a delay unit may be insufficient.

FIG. 2 is a diagram illustrating a layout of the conventional data input circuit of FIG. 1. Referring to FIG. 2, a buffering and delaying unit 21 and a low-level sampling unit 24 are disposed on a pad layer PAD of a memory device, and a high-level sampling unit 25 is disposed on a middle-edge layer and near a circuit layer on which drivers for writing data to a memory core are mounted. The area on which drivers for writing or reading data to or from the memory core are mounted may be referred to as an ‘IOCONT (Input Output Control)’ layer. The pad layer and the middle-edge layer are disposed on a peripheral circuit layer of the memory device, and the IOCONT layer is disposed near the memory core.

Data received via pads DQ4 and DQ5, for example, four serial data streams, are converted into two parallel data streams by a DINI_SA 22, and then output to a DINI 23. The DINI 23 converts the two parallel data streams into four parallel data streams and delays the four parallel data streams by a predetermined time to compensate for delays between the four parallel data streams and a PCLK_WR signal. However, according to this method, current consumption increases due to the presence of a delay circuit, and a delay between a DQS signal and a PCLK_WR signal may increase due to tuning of an absolute delay value, process, voltage and temperature, or PVT, variations, etc.

As illustrated in FIGS. 1 and 2, in a conventional data input circuit, when the data sampled with a DQS signal is edge-sampled with a PCLK_WR signal, the data is first low-sampled and then high-sampled according to the write clock signal PCLK_WR, within a predetermined time interval.

However, this method is not suitable if there is a significant delay between the DQS signal and the PCLK_WR signal. Furthermore, as described above, data skew is not compensated for and the timing margin may insufficient.

### SUMMARY OF THE INVENTION

Exemplary embodiments of the present invention provide a data input circuit of a semiconductor memory device.

According to an exemplary embodiment of the present invention, a data input circuit of a semiconductor memory device comprises: an input buffer that samples an external data signal in response to a data strobe signal and outputs a first-sampled; a first domain converter that samples the first-sampled signal in response to a first clock signal and outputs a second-sampled signal; and a second domain converter sampling the second-sampled signal in response to a second clock signal containing write command information.

The first clock signal may comprise an external system clock signal. The first clock signal may comprise an internal clock signal obtained by delaying the external system clock signal by a predetermined time. The second clock signal may comprise a clock signal containing the write command information obtained by performing an AND operation on a signal containing the write command information and an internal clock signal obtained by delaying the external system clock signal by a predetermined time.

According to another exemplary embodiment of the present invention, there is provided a method for receiving and sampling data to be written to memory cells in a semiconductor memory device, comprising: first sampling an external data signal in response to a data strobe signal; second sampling the first-sampled data signal in response to a first clock signal; and third sampling the second-sampled data signal in response to a second clock signal containing write command information.

The present invention will become more apparent to those of ordinary skill in the art when descriptions of exemplary embodiments thereof are read with reference to the accompanying drawings.

### BRIEF DESCRIPTION OF THE DRAWINGS

FIG. 1 is a block diagram of a conventional data input circuit of a semiconductor memory device.

FIG. 2 is a diagram illustrating a layout of the conventional data input circuit illustrated in FIG. 1.

FIG. 3 is a block diagram of a data input circuit of a semiconductor memory device, according to an exemplary embodiment of the present invention.

FIGS. 4A and 4B are timing diagrams of signals used in the conventional data input circuit illustrated in FIG. 1.

FIGS. 4C and 4D are timing diagrams of signals used in the data input circuit illustrated in FIG. 3.

FIGS. 5A and 5B are timing diagrams for explaining a relationship between data skews in the conventional data input circuit and timing margin in the data input circuit according to an exemplary embodiment of the present invention.

### DETAILED DESCRIPTION OF EXEMPLARY EMBODIMENTS

Hereinafter, exemplary embodiments of the present invention will be described in detail with reference to the accompanying drawings. Like reference numerals refer to similar of identical elements throughout the description of the figures.

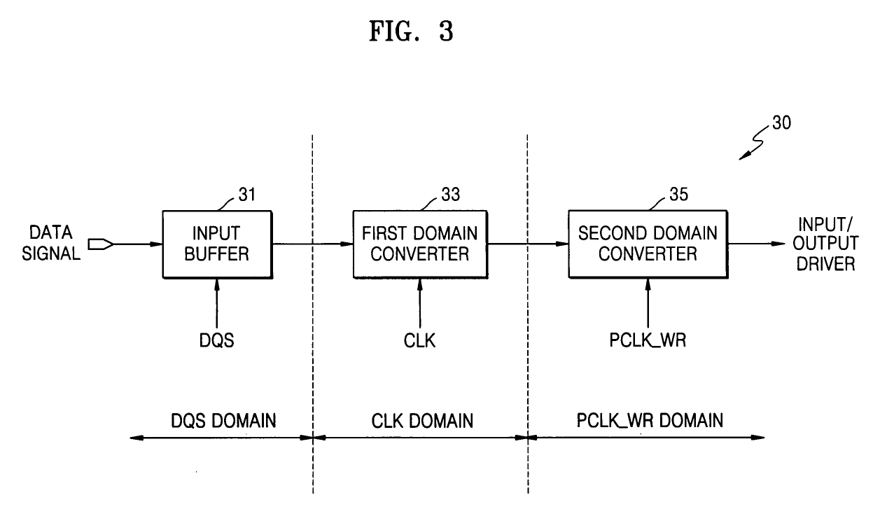

FIG. 3 is a block diagram of a data input circuit 30 of a semiconductor memory device, according to an exemplary embodiment of the present invention. Referring to FIG. 3, the data input circuit 30 includes an input buffer 31, a first domain converter 33, and a second domain converter 35. The input buffer 31 receives a data signal through a data input pad, performs first sampling of the data signal in response to a data strobe signal (hereinafter, referred to as a ‘DQS’ signal), and then outputs the first-sampled data signal to the first domain converter 33. The first domain converter 33 performs second sampling of the data signal in response to a system clock signal (hereinafter, referred to as a ‘CLK’ signal) and outputs the second-sampled data signal to the second domain converter 35. The second domain converter 35 performs third sampling of the data signal in response to a write clock signal (hereinafter, referred to as a ‘PCLK_WR’ signal) containing write command information, and outputs the third-sampled data signal to an input/output driver.

The data signal sampled by the input buffer 31 becomes a signal of a DQS domain. The data signal converted by the first domain converter 33 becomes a signal of a CLK domain. The data signal converted by the second domain converter 35 becomes a signal of a PCLK_WR domain.

Referring to FIG. 3, since a data signal sampled with the DQS signal is also sampled with the CLK signal before being sampled with the PCLK_WR signal, according to an exemplary embodiment of the present invention, it is possible to compensate for a delay between a data signal sampled with the DQS signal and a data signal sampled with the PCLK_WR signal, without adding a separate delay unit to the data path.

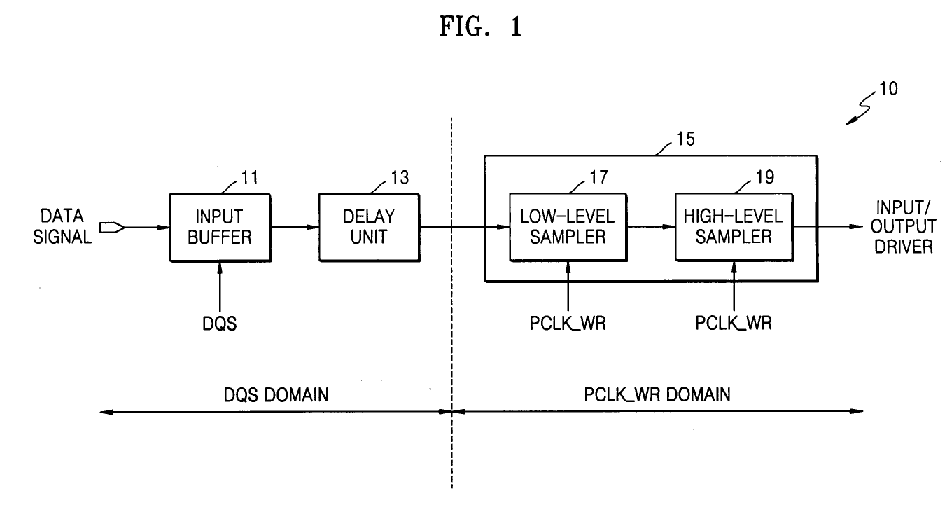

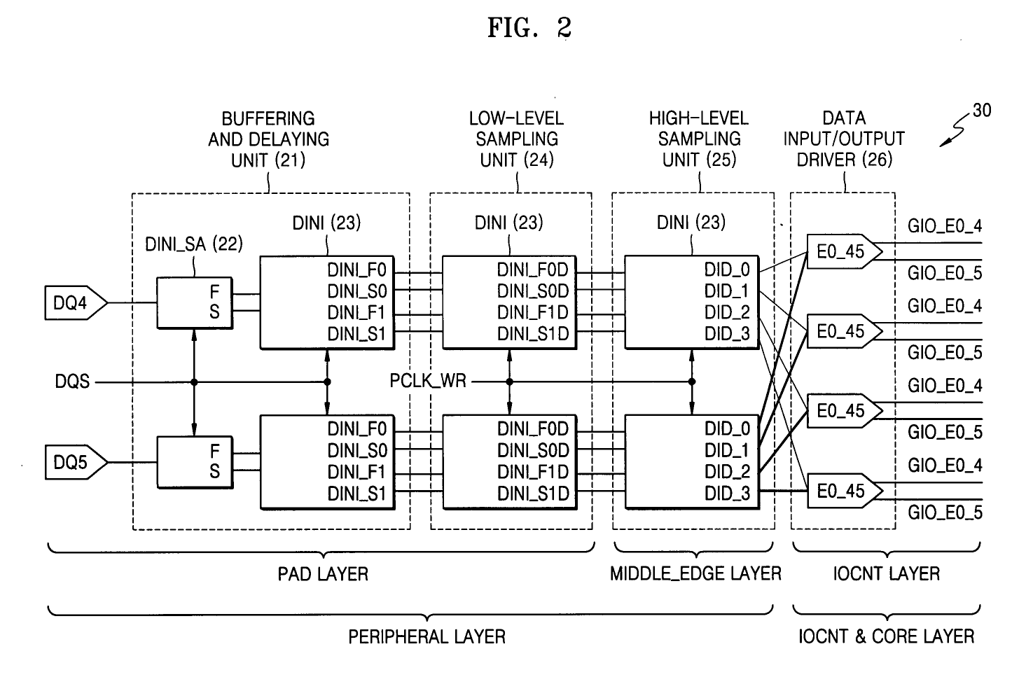

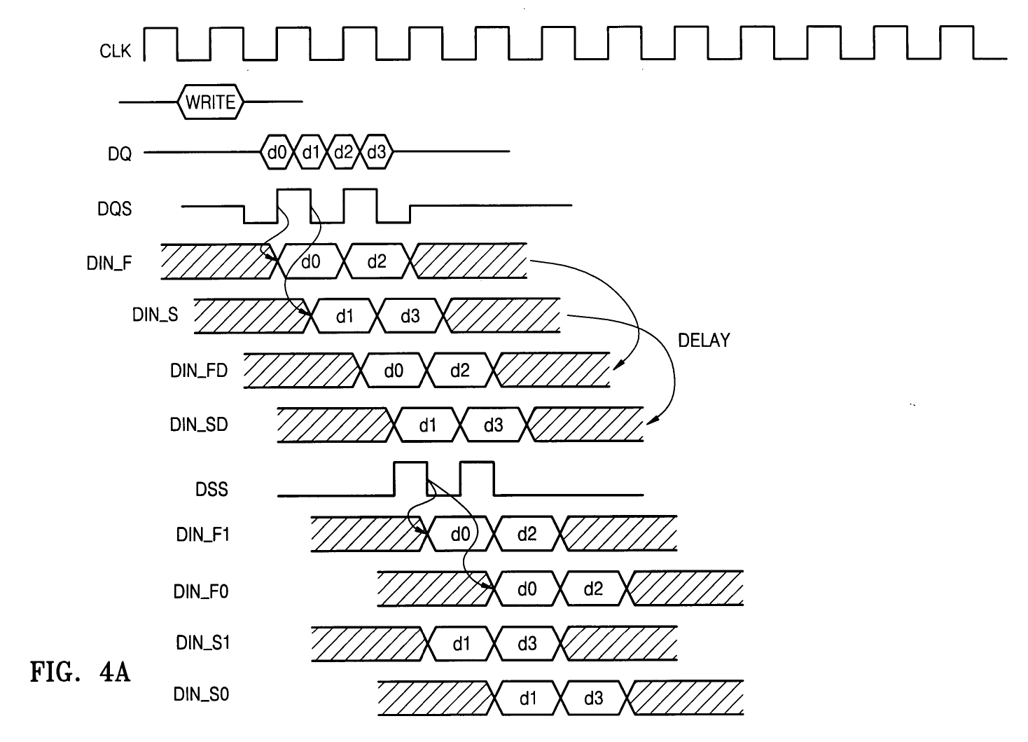

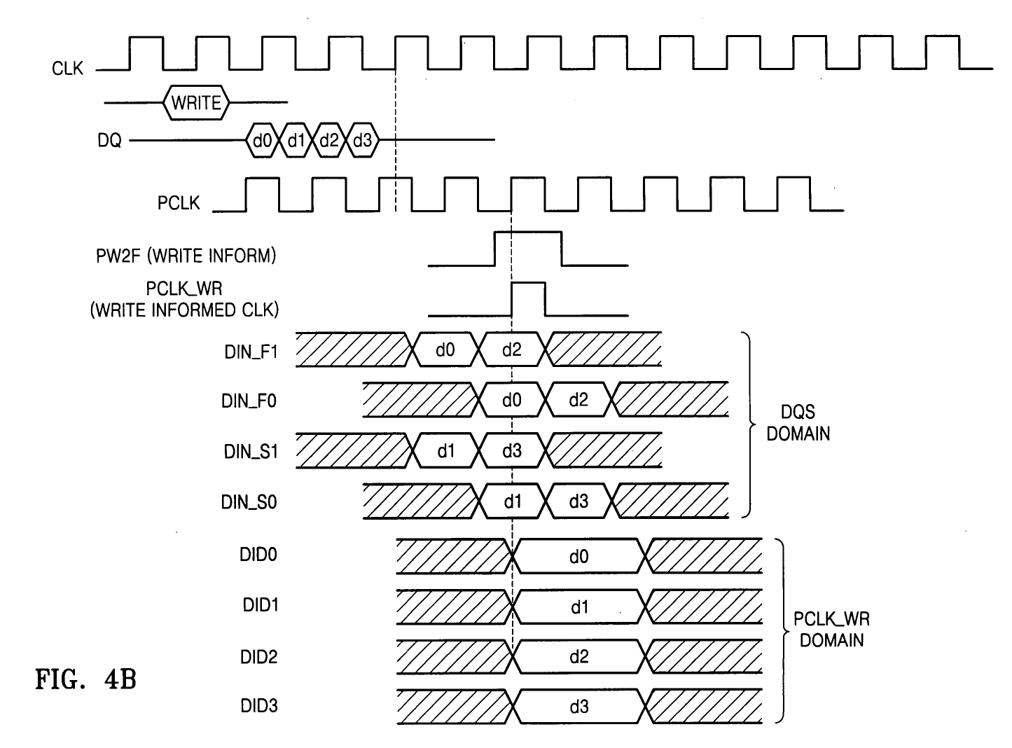

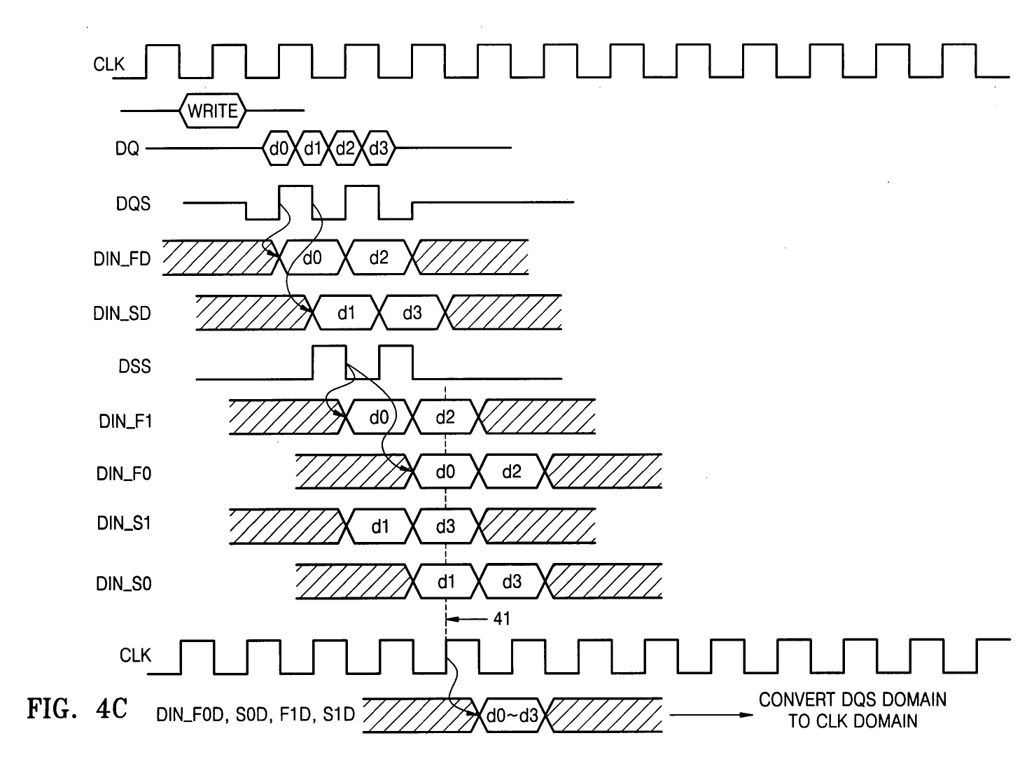

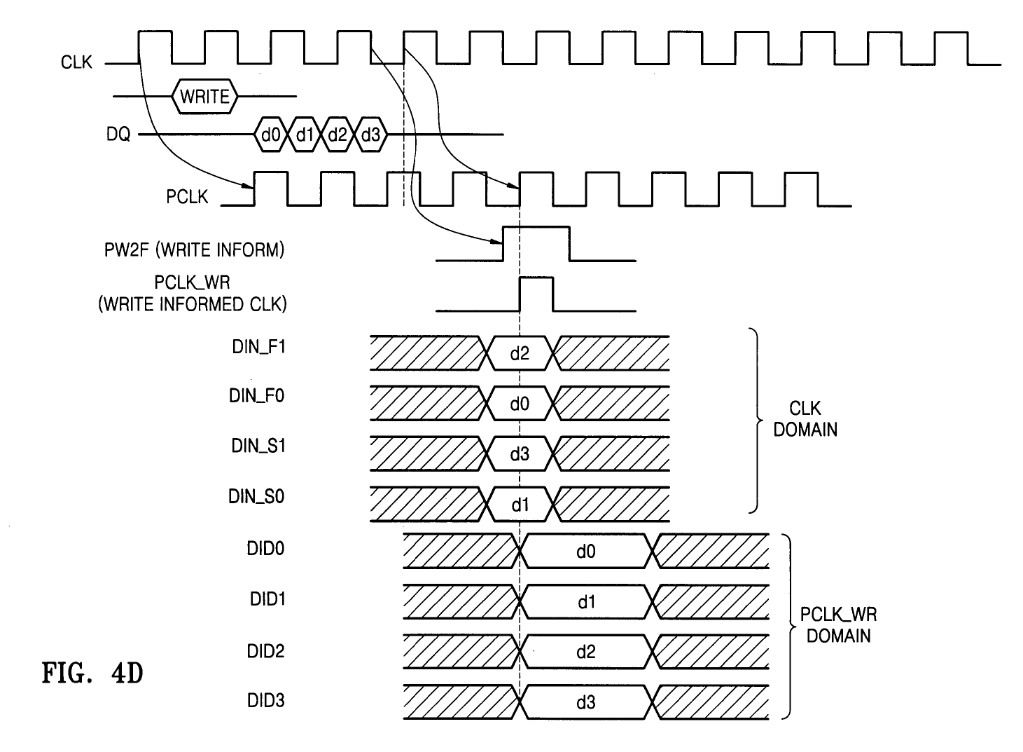

FIGS. 4A and 4B are timing diagrams of signals used in the conventional data input circuit 100 illustrated in FIG. 1. FIGS. 4C and 4D are timing diagrams of signals used in the data input circuit 30, according to an exemplary embodiment of the present invention, illustrated in FIG. 3.

In the timing diagrams shown in FIGS. 4A and 4B, it is assumed that a burst length is 4.

In FIG. 4A, a reference symbol CLK represents an external system clock signal. Referring to FIG. 4A, when a write command is received, a data signal d0 through d3 is received through a pad. The received data signal d0 through d3 is sampled and converted into two parallel signals, for example, a first data input signal DIN_F and a second data input signal DIN_S, in synchronization with the edges of a data strobe signal DQS. The first data input signal DIN_F is obtained by sampling the data signal d0 through d3 at the rising edges of the data strobe signal DQS and contains the odd-th data of the data signal d0 through d3. The second data input signal DIN_S is obtained by sampling the data signal d0 through d3 at the falling edges of the data strobe signal DQS and contains the even-th data of the data signal d0 through d3.

The first and second data input signals DIN_S and DIN_F are delayed by a PCLK_WR signal through a delay unit and respectively become delayed data input signals DIN_FD and DIN_SD.

The delayed data input signals DIN_FD and DIN_SD are converted into four parallel data signals DIN_F1, DIN_F0, DIN_S1, and DIN_S0, in response to a delayed DQS signal DSS. In an exemplary embodiment of the present invention, the data signal DIN_F0 is created by delaying the data signal DIN_F1 by one period and the data signal DIN_S0 is created by delaying the data signal DIN_S1 by one period.

In FIG. 4B, a reference symbol PCLK represents an internal clock signal delayed from the CLK signal, a reference symbol PW2F represents a signal containing write command information, and a reference symbol PCLK_WR represents a write clock signal activated when the signal PW2F is high. The write clock signal (hereinafter, referred to as a ‘PCLK_WR’ signal) is a clock signal containing write command information.

Referring to FIG. 4B, the four parallel signals DIN_F1, DIN_F0, DIN_S1, and DIN_S0 are sampled in synchronization with the PCLK_WR signal and converted into four parallel signals DID0 through DID3. The four parallel data DID0 through DID3 become a signal of a PCLK_WR domain.

Referring to FIG. 4C, a data stream received through a pad is converted into four parallel signals DIN_F1, DIN_F0, DIN_S1, and DIN_S0 in synchronization with a DQS signal by the input buffer 31, as in FIG. 4A. Then, the four parallel signals DIN_F1, DIN_F0, DIN_S1, and DIN_S0 are subjected to second sampling in synchronization with a CLK signal.

In an exemplary embodiment of the present invention, since the CLK signal has a constant period, no delay exists between the CLK signal and the DQS signal. When the four parallel signals DIN_F1, DIN_F0, DIN_S1, and DIN_S0 are transmitted, they are second-sampled at the rising edges of the CLK signal and converted into signals DIN_F0D, S0D, F1D and S1D. Delay compensation for the four parallel signals DIN_F1, DIN_F0, DIN_S1, and DIN_S0 is not needed. The second-sampled data signals DIN_F0D, S0D, F1D and S1D are delayed due to sampling by the CLK signal. The second-sampled data signals DIN F0D, S0D, F1D and S1D become signals of the CLK domain.

Referring to FIG. 4D, the second-sampled data signals DIN_F0D, S0D, F1D and S1D are subjected to third sampling in synchronization with a PCLK_WR signal containing write command information, and thus converted into third-sampled data DID0 through DID3. Since the second-sampled data is activated on the rising edge of the PCLK_WR signal, no delay compensation is needed. The third-sampled data signals DID0 through DID3 become signals of a PCLK_WR domain.

The data input circuit 30 of FIG. 3, according to an exemplary embodiment the present invention, samples received data with a system clock signal before sampling it with a PCLK_WR signal. Since the system clock signal does not require delay compensation with respect to the DQS signal, no delay unit is needed. According to exemplary embodiments of the present invention, power consumption can be reduced and a shortest data path can be implemented, which minimizes effects on a memory device due to PVT variations, facilitating a design of a memory device. According to exemplary embodiments of the present invention, since the data path is shortened and the absolute delay of the corresponding internal clock signal PCLK is reduced, it is possible to set a delay tDQSCK between a data strobe signal DQS and an internal clock signal PCLK according to a desired specification.

When a memory device is designed in accordance with exemplary embodiments of the present invention, a delay between an internal clock signal PCLK and a write clock signal PCLK_WR can depend on PVT variations; however, since the absolute delay therebetween is not large, delay skew does not substantially increase. Also, since the delay is not associated with the delay tDQSCK based on the specification, according to exemplary embodiments of the present invention it is possible to increase a timing margin when a memory device is designed.

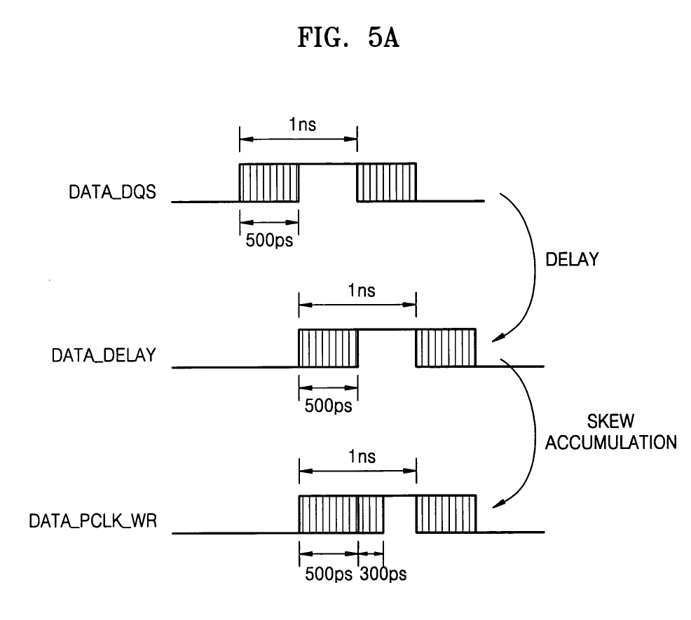

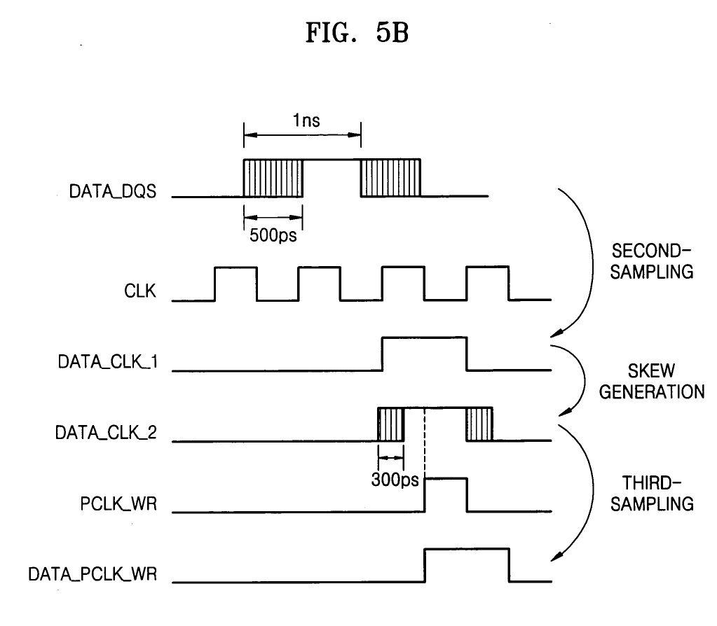

FIGS. 5A and 5B are timing diagrams for explaining a relationship between data skews in the conventional data input circuit 100 and timing margin in the data input circuit 30 according to an exemplary embodiment of the present invention.

FIG. 5A is a timing diagram illustrating a case of sampling data using the conventional data input circuit 10. In FIG. 5A, it is assumed that a data signal has a period of 1 ns and that a data signal DATA_DQS of a DQS domain passed through the input buffer 11 has a skew of 500 ps. In such case, the signal DATA_DQS passed through the delay unit 13 of FIG. 1 still has a skew of 500 ps. When the data signal DATA_DQS output from the delay unit 13 is input to the domain converter 15 (see FIG. 1), a skew of 300 ps generated in a PCLK_WR domain is further accumulated due to a different data path and power. Accordingly, as illustrated in FIG. 5A, timing margin capable of correctly sampling data in the domain converter 15 becomes only 200 ps.

FIG. 5B is a timing diagram illustrating a case of sampling data using the data input circuit 30 of FIG. 3, according to an exemplary embodiment of the present invention. In FIG. 5B, it is assumed that a data signal DATA_DQS of a DQS domain passed through the input buffer 31 of FIG. 3 has a skew of 500 ps, for example. In such case, if the data signal DATA_DQS is second-sampled in synchronization with a CLK signal, the resultant data DATA_CLK_1 can be sampled with a timing margin of 500 ps and the previous skews of the second-sampled data DATA_CLK_1 are completely removed. Then, the data signal DATA_CLK_1 is input to the second domain converter 35 of FIG. 3. The data signal DATA_CLK_1 input to the second domain converter 35 becomes data DATA_CLK_2 having a data skew of 300 ps due to a different path and power, as in FIG. 5A. As a result, in an exemplary embodiment of the present invention, in this example case, since a skew of 300 ps exists when previous skews are completely removed, a timing margin of 700 ps can be ensured when the data DATA_CLK_2 is third-sampled in the secondary domain converter 35.

As described above, in a data input circuit of a semiconductor memory device, according to exemplary embodiments of the present invention, it is possible to compensate for delays between a data strobe signal and a write clock signal and prevent data skews from being accumulated, without adding a delay unit to a data path controlled by the data strobe signal, and to stably perform data sampling.

Although the exemplary embodiments of the present invention have been described with reference to the accompanying drawings for the purpose of illustration, it is to be understood that the inventive processes and apparatus are not to be construed as limited thereby. It will be readily apparent to those of ordinary skill in the art that various modifications to the foregoing exemplary embodiments may be made without departing from the scope of the invention as defined by the appended claims, with equivalents of the claims to be included therein.

What is claimed is:

1. A data input circuit of a semiconductor memory device comprising:
an input buffer that samples an external data signal in response to a data strobe signal and outputs a first-sampled signal;
a first domain converter that samples the first-sampled signal in response to a first clock signal and outputs a second-sampled signal; and
a second domain converter that samples the second-sampled signal in response to a second clock signal containing write command information.

2. The data input circuit of claim 1, wherein the input buffer receives serial data and converts the serial data into parallel data.

3. The data input circuit of claim 1, wherein the input buffer samples the external data signal at rising and falling edges of the data strobe signal, wherein the first domain converter samples the first-sampled signal at rising edges of the first clock signal, and wherein the second domain converter samples the second-sampled signal at rising edges of the second clock signal.

4. The data input circuit of claim 1, wherein the first clock signal comprises an external system clock signal.

5. The data input circuit of claim 1, wherein the first clock signal comprises an internal clock signal obtained by delaying the external system clock signal by a predetermined time.

6. The data input circuit of claim 4, wherein the second clock signal comprises a clock signal containing the write command information obtained by performing an AND operation on a signal containing the write command information and an internal clock signal obtained by delaying the external system clock signal by a predetermined time.

7. The data input circuit of claim 5, wherein the second clock signal comprises a clock signal containing the write command information, obtained by performing an AND operation on the internal clock signal and a signal containing the write command information.

8. The data input circuit of claim 1, wherein the memory device comprises a synchronous semiconductor memory device.

9. A method for receiving and sampling data to be written to memory cells in a semiconductor memory device, comprising:
first sampling an external data signal in response to a data strobe signal;
second sampling the first-sampled data signal in response to a first clock signal; and
third sampling the second-sampled data signal in response to a second clock signal containing write command information.

10. The method of claim 9, wherein the first sampling comprises receiving serial data and converting the serial data into parallel data.

11. The method of claim 9, wherein the first sampling comprises sampling the external data signal at rising and falling edges of the data strobe signal, wherein the second sampling comprises sampling the first-sampled data signal at rising edges of the first clock signal, and wherein the third sampling comprises sampling the second-sampled data signal at rising edges of the second clock signal.

12. The method of claim 9, wherein the first clock signal comprises an external clock signal.

13. The method of claim 9, wherein the first clock signal comprises an internal clock signal obtained by delaying an external clock signal by a predetermined time.

14. The method of claim 12, wherein the second clock signal comprises a clock signal containing the write command information, obtained by performing an AND operation on an internal clock signal obtained by delaying an external clock signal by a predetermined time and a signal indicating the write command information.

15. The method of claim 13, wherein the second clock signal comprises a clock signal containing the write command information, obtained by performing an AND operation on the internal clock signal and a signal indicating the write command information.
